(19) United States
(12) Patent Application Publication
(10) Pub. No.: US 2006/0113876 A1
(43) Pub. Date: Jun. 1, 2006

(54) Piezoelectric/electrostrictive device

(75) Inventors: Koji Ikeda, Hisai-City (JP); Kazuyoshi Shibata, Mizunami-City (JP)

Correspondence Address: BURR & BROWN, PO BOX 7068, SYRACUSE, NY, 13261-7068, US

(73) Assignee: NGK Insulators Ltd., Nagoya-City (JP)

(21) Appl. No.: 11/334,147

(22) Filed: Jan. 18, 2006

Related U.S. Application Data
(63) Continuation of application No. PCT/JP04/12412, filed on Aug. 23, 2004.

(30) Foreign Application Priority Data
Aug. 21, 2003 (JP) 2003-297033

(51) Int. Cl. H01L 41/04

(52) U.S. Cl. 310/341; 310/365

(57) ABSTRACT

A piezoelectric/electrostrictive device 10 includes a stationary portion 11; a thin-plate portion 12 supported by the stationary portion; and a piezoelectric/electrostrictive element 14 including a plurality of electrodes and a plurality of piezoelectric/electrostrictive layers which are laminated alternately. The piezoelectric/electrostrictive device 10 is manufactured as follows: firstly, a piezoelectric/electrostrictive laminate composed of laminar electrodes and piezoelectric/electrostrictive layers is formed on the surface of a thin-plate body which is to become the thin-plate portion 12; subsequently, the thin-plate body and the piezoelectric/electrostrictive laminate are cut; and the resultant cut surface (lateral end surface) is finished through polishing, so as to attain an arithmetic average surface roughness of 0.05 μm or less. This finishing process enables occurrence of uniform residual strain in the vicinity of the lateral end surface, as well as elimination of microcracks generated in the vicinity of the lateral end surface through the above cutting, thereby effectively preventing particle separation from the lateral end surface.

### TECHNICAL FIELD

The present invention relates to a piezoelectric/electrostrictive device including a stationary portion, a thin-plate portion supported by the stationary portion, and a piezoelectric/electrostrictive element including laminar electrodes and a piezoelectric/electrostrictive layer.

### BACKGROUND ART

Piezoelectric/electrostrictive devices of the above-described type have been actively developed as an actuator for precision machining; as an actuator for controlling the position of a read and/or write element (e.g., a magnetic head of a hard disk drive) for reading and/or writing optical information, magnetic information, or the like; as a sensor for converting mechanical vibration to an electrical signal; or as a similar device.

Japanese Patent Application Laid-Open (kokai) No. 2001-320103 discloses an example of such a piezoelectric/electrostrictive device, which is shown in FIG. 13. The piezoelectric/electrostrictive device includes a stationary portion 100; thin-plate portions 110 supported by the stationary portion 100; holding portions (movable portions) 120 provided at corresponding tip ends of the thin-plate portions 110 and adapted to hold an object (e.g., a magnetic head of a hard disk drive); and piezoelectric/electrostrictive elements 130 formed at least on corresponding surfaces of the thin-plate portions 110, each piezoelectric/electrostrictive element 130 including a plurality of electrodes and a plurality of piezoelectric/electrostrictive layers which are laminated alternately. In the piezoelectric/electrostrictive device, an electric field is generated between electrodes of the piezoelectric/electrostrictive elements 130 to thereby expand and contract the piezoelectric/electrostrictive layers of the piezoelectric/electrostrictive elements 130, whereby the thin-plate portions 110 are deformed. The deformation of the thin-plate portions 110 causes displacement of the holding portions 120 (accordingly, displacement of the object held by the holding portions 120).

The piezoelectric/electrostrictive device of FIG. 13 is manufactured as follows. Firstly, as shown in FIG. 14, a plurality of ceramic green sheets (and/or a ceramic green sheet laminate) are prepared. As shown in FIG. 15, these ceramic green sheets are laminated together and then fired, thereby forming a ceramic laminate 200. As shown in FIG. 16, piezoelectric/electrostrictive laminates 210, each including a plurality of electrodes and a plurality of piezoelectric/electrostrictive layers which are laminated alternately, are formed on the surface of the ceramic laminate 200. Through wire sawing (or, for example, dicing) by use of a wire saw WS, the piezoelectric/electrostrictive laminates 210 are cut along cutting lines C1 to C4 shown in FIG. 17, thereby yielding the piezoelectric/electrostrictive device.

In the case where the above-disclosed piezoelectric/electrostrictive device is employed as, for example, an actuator for controlling the position of a magnetic head of a hard disk drive, adhesion of debris, dust, or the like onto the hard disk, etc., may cause incorrect reading/writing of data. Therefore, the piezoelectric/electrostrictive device is to be placed in the environment in which generation of debris, dust, or the like (hereinafter, generation of debris, dust, or the like may be referred to as “dust generation”) should be suppressed to the lowest possible level.

In such a case, the above-disclosed piezoelectric/electrostrictive device is employed such that a lateral end surface of the device (i.e., a cut surface along the cutting line C3 or C4 of FIG. 17), which forms a single flat surface, faces the surface of the hard disk so as to provide a relatively small gap between the lateral end surface and the hard disk surface. Therefore, particularly, there must be prevented dust generation caused by separation of microparticles (hereinafter, separation of particles may be referred to as “particle separation”) from the lateral end surfaces of the constituents of the piezoelectric/electrostrictive device (i.e., cut surfaces along the cutting line C3 or C4 of FIG. 17), which form a single flat surface.

In the above-disclosed piezoelectric/electrostrictive device, the stationary portion 100, the thin-plate portions 110, and the holding portions 120 are formed of, for example, a ceramic material containing, as a primary component, (partially stabilized) zirconia having high mechanical strength and toughness. The plurality of electrodes (i.e., constituents) of the piezoelectric/electrostrictive element 130 are formed of, for example, a metal having high ductility, such as platinum, and the piezoelectric/electrostrictive layers (i.e., constituents) of the element 130 are formed of, for example, a piezoelectric ceramic material containing, as a primary component, lead zirconate titanate (PZT) having relatively low strength and high fragility. Such a fragile material of relatively low strength is likely to cause particle separation through, for example, application of repeated stress. Therefore, among the lateral end surfaces (cut surfaces) of the constituents of the piezoelectric/electrostrictive device, particle separation is most likely to occur at the lateral end surfaces of the piezoelectric/electrostrictive layers formed of the piezoelectric ceramic material.

In general, particle separation from a cut surface of a material is caused by, for example, the following phenomenon: distribution of strain remaining in the vicinity of the cut surface after cutting (i.e., distribution of residual stress) becomes non-uniform due to large irregularities of the cut surface, and abnormally high stress (stress concentration) occurs locally in the vicinity of the cut surface upon deformation of the material, resulting in breakage of the material; or microcracks are generated in the vicinity of the cut surface of the material through application of load to the material during the course of cutting, and the microcracks grow through application of repeated stress to the material, resulting in breakage of the material.

Thus, in order to suppress, to the lowest possible level, dust generation caused by particle separation from the lateral end surfaces of the aforementioned piezoelectric/electrostrictive layers (i.e., cut surfaces along the cutting line C3 or C4 of FIG. 17), the irregularities of the lateral end surfaces (cut surfaces) of the piezoelectric/electrostrictive layers must be reduced to the lowest possible extent. In order to reduce the surface irregularities, the lateral end surface of the aforementioned piezoelectric/electrostrictive device must be formed through cutting at the lowest possible cutting speed by use of abrasive grains having the smallest possible grain size. However, such a cutting process involves a problem in that the process requires a considerably long period of time.

When microcracks are generated through the above cutting process, the piezoelectric/electrostrictive layers must be subjected to a predetermined thermal treatment for elimination of the microcracks. This thermal treatment eliminates the microcracks generated in the piezoelectric/electrostrictive layers through solid-phase reaction in the layers, and suppresses particle separation through vitrification of the material of the layers. However, when such a predetermined thermal treatment is performed rapidly within a short period of time, or performed at an inappropriate temperature, thermal strain may occur in the piezoelectric/electrostrictive device, leading to reduction in the dimensional accuracy of the device. Therefore, such a predetermined thermal treatment must be performed over a relatively long period of time under strict temperature control.

### DISCLOSURE OF THE INVENTION

In view of the foregoing, an object of the present invention is to provide a piezoelectric/electrostrictive device which can be manufactured at high productivity and which enables effective prevention of particle separation from lateral end surfaces (worked surfaces) of a piezoelectric/electrostrictive layer constituting a piezoelectric/electrostrictive element.

In order to achieve the above object, the present invention provides a piezoelectric/electrostrictive device comprising a thin-plate portion; a stationary portion supporting the thin-plate portion; and a piezoelectric/electrostrictive element formed at least on a flat surface of the thin-plate portion, the piezoelectric/electrostrictive element including a plurality of electrodes and at least one piezoelectric/electrostrictive layer which are laminated together, a lateral end surface of the piezoelectric/electrostrictive element, which forms a single flat surface, being composed of respective lateral end surfaces of the plurality of electrodes and a lateral end surface of said at least one piezoelectric/electrostrictive layer, characterized in that the lateral end surface of the piezoelectric/electrostrictive layer has an arithmetic average surface roughness of 0.05 μm or less.

Preferably, the lateral end surface of the piezoelectric/electrostrictive layer is formed by polishing the lateral end surface of the piezoelectric/electrostrictive element, which forms the single flat surface.

The lateral end surface (cut surface or worked surface) of the piezoelectric/electrostrictive layer (accordingly, the lateral end surface of the piezoelectric/electrostrictive element (piezoelectric/electrostrictive device), which forms the aforementioned single flat surface), which has an arithmetic average surface roughness of 0.05 μm or less, can be formed by finishing, through polishing or a similar technique, of a rough surface of the layer obtained by mechanical machining such as wire sawing (or dicing), laser machining (e.g., YAG laser machining), or electron beam machining.

This finishing of the rough surface through polishing (or a similar technique) reduces irregularities of the lateral end surface of the piezoelectric/electrostrictive layer to a very small level, whereby uniform residual strain (i.e., residual stress) occurs in the vicinity of the lateral end surface. Therefore, when, for example, the piezoelectric/electrostrictive layer is deformed during operation of the piezoelectric/electrostrictive device, the aforementioned local occurrence of abnormally high stress (stress concentration) in the vicinity of the lateral end surface is prevented, and thus particle separation tends not to occur.

Microcracks generated in the vicinity of the lateral end surface (i.e., the aforementioned rough surface) of the piezoelectric/electrostrictive layer through the aforementioned mechanical machining or the like can be eliminated by means of polishing, etc. performed on the rough surface. Thus, even when repeated stress generated through operation of the piezoelectric/electrostrictive device is applied to the piezoelectric/electrostrictive layer, particle separation, which is caused by growth of the microcracks, does not occur.

Therefore, the piezoelectric/electrostrictive device which has undergone the aforementioned mechanical machining or the like is not required to be subjected to the above-described thermal treatment for elimination of microcracks in order to prevent particle separation from the lateral end surface of the piezoelectric/electrostrictive layer, the thermal treatment causing productivity reduction. In addition, the time required for the aforementioned mechanical machining or the like can be shortened, since polishing, etc. is performed after the mechanical machining or the like, and thus the size of irregularities of the rough surface formed by the mechanical machining or the like is not necessarily regulated to a relatively small level. In other words, the piezoelectric/electrostrictive device of the present invention can be readily manufactured within a relatively short period of time; i.e., the productivity of the device is high. That is, the piezoelectric/electrostrictive device provided by the present invention can be manufactured at high productivity, and enables effective prevention of particle separation from the lateral end surface (worked surface) of the piezoelectric/electrostrictive layer, which is a constituent of the piezoelectric/electrostrictive element.

### BRIEF DESCRIPTION OF THE DRAWINGS

FIG. 1 is a perspective view showing a piezoelectric/electrostrictive device according to an embodiment of the present invention.

FIG. 2 is a perspective view showing the piezoelectric/electrostrictive device of FIG. 1 and an object held by the piezoelectric/electrostrictive device.

FIG. 3 is an enlarged fragmental front view showing the piezoelectric/electrostrictive device of FIG. 1.

FIG. 4 is a perspective view showing a modification of the piezoelectric/electrostrictive device of FIG. 1.

FIG. 5 is a perspective view showing ceramic green sheets to be laminated in a method for manufacturing a piezoelectric/electrostrictive device according to the present invention.

FIG. 6 is a perspective view showing a ceramic green sheet laminate formed by laminating and compression-bonding the ceramic green sheets of FIG. 5.

FIG. 7 is a perspective view showing a ceramic laminate formed by monolithically firing the ceramic green sheet laminate of FIG. 6.

FIG. 8 is a perspective view showing the ceramic laminate of FIG. 7 on which piezoelectric/electrostrictive laminates are formed.

FIG. 9 illustrates a step of cutting the ceramic laminate and the piezoelectric/electrostrictive laminates shown in FIG. 8.

FIG. 10 is a perspective view showing another modification of the piezoelectric/electrostrictive device of FIG. 1.

FIG. 11 shows another example in which an object is held on the piezoelectric/electrostrictive device of FIG. 1.

FIG. 12 is a perspective view showing yet another modification of the piezoelectric/electrostrictive device of FIG. 1.

FIG. 13 is a perspective view showing a conventional piezoelectric/electrostrictive device.

FIG. 14 is a perspective view showing ceramic green sheets to be laminated in the process of manufacturing the piezoelectric/electrostrictive device of FIG. 13.

FIG. 15 is a perspective view showing a ceramic laminate formed by monolithically firing a ceramic green sheet laminate formed by laminating and compression-bonding the ceramic green sheets of FIG. 14.

FIG. 16 is a perspective view showing the ceramic laminate of FIG. 15 on which piezoelectric/electrostrictive laminates are formed.

FIG. 17 illustrates a step of cutting the ceramic laminate and the piezoelectric/electrostrictive laminates shown in FIG. 16.

### BEST MODE FOR CARRYING OUT THE INVENTION

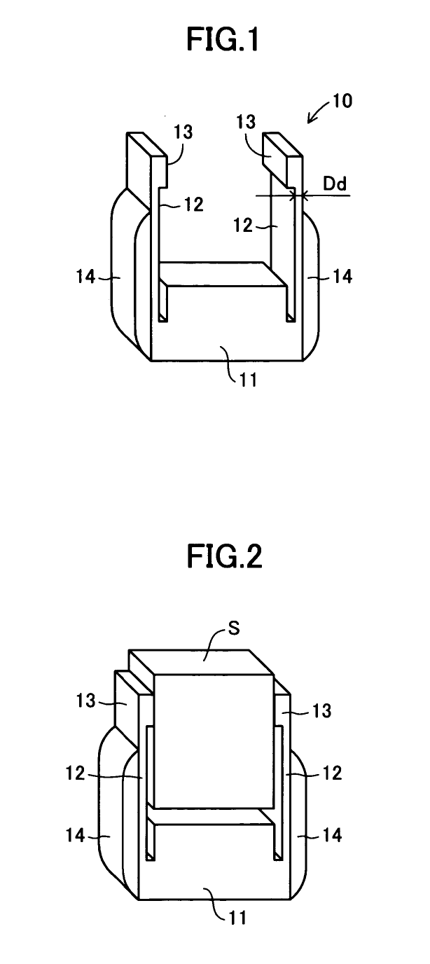

An embodiment of a piezoelectric/electrostrictive device according to the present invention will next be described with reference to the drawings. As shown in the perspective view of FIG. 1, a piezoelectric/electrostrictive device 10 according to the present embodiment includes a stationary portion 11 in the shape of a rectangular parallelepiped; a pair of mutually facing thin-plate portions 12, which are supported by the stationary portion 11 in a standing condition; holding portions (movable portions) 13 provided at corresponding tip ends of the thin-plate portions 12 and having a thickness greater than that of the thin-plate portions 12; and piezoelectric/electrostrictive elements 14 formed at least on corresponding outer surfaces of the thin-plate portions 12 and including laminar electrodes and piezoelectric/electrostrictive layers which are laminated alternately. The general configurations of these portions are disclosed in, for example, Japanese Patent Application Laid-Open (kokai) No. 2001-320103.

As shown in FIG. 2, the piezoelectric/electrostrictive device 10 is employed, for example, as an actuator in which an object S is held between the paired holding portions 13, and force generated by the piezoelectric/electrostrictive elements 14 causes the thin-plate portions 12 to be deformed to thereby displace the holding portions 13 for controlling the position of the object S. The object S is a magnetic head, an optical head, a sensitivity-adjusting weight for use in a sensor, or the like.

A portion (also generically called a “substrate portion”) constituted by the stationary portion 11, the thin-plate portions 12, and the holding portions 13 is formed of a ceramic laminate, which is formed by firing a laminate of ceramic green sheets as will be described below in detail. Such a monolithic ceramic element does not employ an adhesive for joining its portions and is thus almost free from a change in state with passage of time, thereby providing a highly reliable joint and having advantage in terms of attainment of rigidity. The ceramic laminate can be readily manufactured by a ceramic green sheet lamination process, which will be described below.

The entirety of the substrate portion may be formed from a ceramic material or a metal, or may assume a hybrid structure in which a ceramic material and a metal are employed in combination. Also, the substrate portion may be configured such that ceramic pieces are bonded together by means of an adhesive, such as an organic resin or glass, or such that metallic pieces are joined together through brazing, soldering, eutectic bonding, diffusion joining, welding, or a similar technique.

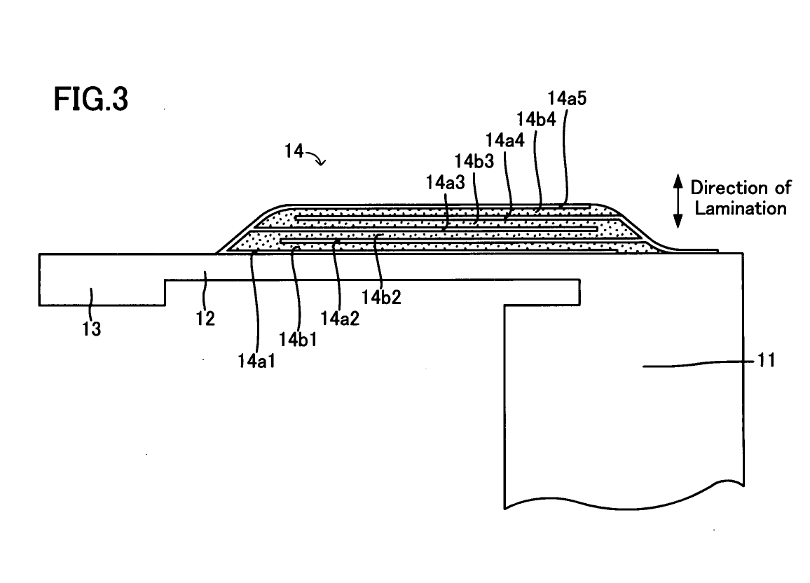

As shown in the enlarged view of FIG. 3, the piezoelectric/electrostrictive element 14 is formed on an outer wall surface (outer surface) formed by the stationary portion 11 (or a portion of the stationary portion) and the thin-plate portion 12 (or a portion of the thin-plate portion), includes a plurality of laminar electrodes and a plurality of piezoelectric/electrostrictive layers, and assumes the form of a laminate in which the laminar electrodes and the piezoelectric/electrostrictive layers are laminated alternately. The electrode layers and the piezoelectric/electrostrictive layers are parallel to the surface of the thin-plate portion 12. More specifically, the piezoelectric/electrostrictive element 14 is a laminate in which an electrode 14a1, a piezoelectric/electrostrictive layer 14b1, an electrode 14a2, a piezoelectric/electrostrictive layer 14b2, an electrode 14a3, a piezoelectric/electrostrictive layer 14b3, an electrode 14a4, a piezoelectric/electrostrictive layer 14b4, and an electrode 14a5 are laminated in that order on the outer surface of the thin-plate portion 12. The electrodes 14a1, 14a3, and 14a5 are electrically connected together and are insulated from the electrically connected electrodes 14a2 and 14a4. In other words, the electrically connected electrodes 14a1, 14a3, and 14a5 and the electrically connected electrodes 14a2 and 14a4 are arranged in a shape resembling the teeth of a comb.

The piezoelectric/electrostrictive element 14 is formed integrally with the substrate portion by a film formation process, which will be described below. Alternatively, the piezoelectric/electrostrictive element 14 may be manufactured separately from the substrate portion, followed by a process of joining the piezoelectric/electrostrictive element 14 to the substrate portion by use of an adhesive, such as an organic resin, or by means of glass, brazing, soldering, eutectic bonding, or a similar technique.

The present embodiment shows a multi-layered structure including five electrode layers; however, no particular limitation is imposed on the number of layers. In general, as the number of layers increases, a force (drive force) for deforming the thin-plate portions 12 increases, but power consumption also increases. Accordingly, the number of layers can be appropriately determined in accordance with, for example, application and the state of use.

A supplementary description of component elements of the piezoelectric/electrostrictive device 10 will next be given below.

The holding portions 13 operate on the basis of displacement of the thin-plate portions 12. Various members are attached to the holding portions 13 in accordance with applications of the piezoelectric/electrostrictive device 10. For example, when the piezoelectric/electrostrictive device 10 is employed as an element (displacing element) for displacing an object, particularly when the piezoelectric/electrostrictive 10 is employed for positioning or suppressing wringing of a magnetic head of a hard disk drive, a slider having a magnetic head, a magnetic head, a suspension having a slider, or a similar member (i.e., a member required to be positioned) may be attached. Also, the shield of an optical shutter or the like may be attached.

As described above, the stationary portion 11 is adapted to support the thin-plate portions 12 and the holding portions 13. When the piezoelectric/electrostrictive device 10 is employed for, for example, positioning the magnetic head of a hard disk drive, the stationary portion 11 is fixedly attached to a carriage arm attached to a VCM (voice coil motor), to a fixture plate attached to the carriage arm, to a suspension, or to a similar member. In some cases, unillustrated terminals and other members for driving the piezoelectric/electrostrictive elements 14 are provided on the stationary portion 11. The terminals may have a width similar to that of the electrodes or may be narrower or partially narrower than the electrodes.

No particular limitation is imposed on the material for forming the holding portions 13 and the stationary portion 11, so long as the holding portions 13 and the stationary portion 11 have rigidity. In general, employment of a ceramic material as the material for these portions is preferred, since a ceramic green sheet lamination process, which will be described below, can be applied. Specific examples of the material include a material containing, as a primary component, zirconia (such as stabilized zirconia or partially stabilized zirconia), alumina, magnesia, silicon nitride, aluminum nitride, or titanium oxide; and a material containing a mixture of them as a primary component. A material containing, as a primary component, zirconia (in particular, stabilized zirconia or partially stabilized zirconia) is preferred for the piezoelectric/electrostrictive device 10, since such a material has high mechanical strength and toughness. When a metallic material is to be employed for manufacturing the holding portions 13 and the stationary portion 11, stainless steel, nickel, or the like is preferred as the metallic material.

As described above, the thin-plate portions 12 are driven by the piezoelectric/electrostrictive elements 14. The thin-plate portions 12 are thin-plate-like members having flexibility and have a function for converting expansion/contraction displacement of the piezoelectric/electrostrictive elements 14 disposed on their surfaces to bending displacement and transmitting the bending displacement to the corresponding holding portions 13. Accordingly, no particular limitation is imposed on the shape of and the material for the thin-plate portions 12, so long as the thin-plate portions 12 are flexible and have such mechanical strength as not to be broken from bending deformation; and the shape and material are selected in view of, for example, response and operability of the holding portions 13.

The thickness Dd (see FIG. 1) of the thin-plate portion 12 is preferably about 2 μm to about 100 μm; and the total thickness of the thin-plate portion 12 and the piezoelectric/electrostrictive element 14 is preferably 7 μm to 500 μm. The thickness of each of the electrodes 14a1 to 14a5 is preferably 0.1 μm to 50 μm; and the thickness of each of the piezoelectric/electrostrictive layers 14b1 to 14b5 is preferably 3 μm to 300 μm.

Preferably, as in the case of the holding portions 13 and the stationary portion 11, a ceramic material is employed for forming the thin-plate portions 12. Among ceramic materials, a material containing, as a primary component, zirconia (in particular, stabilized zirconia or partially stabilized zirconia) is more preferred, since such a material exhibits, even when having a small thickness, high mechanical strength and high toughness, and it has low reactivity with the electrode material of the electrodes 14a1 and the piezoelectric/electrostrictive layers 14b1, which constitute the piezoelectric/electrostrictive element 14.

The thin-plate portions 12 can also be formed from a metallic material that has flexibility and allows bending deformation. Among preferred metallic materials for the thin-plate portions 12, examples of ferrous materials include stainless steels and spring steels, and examples of nonferrous materials include beryllium copper, phosphor bronze, nickel, and nickel-iron alloys.

Preferably, stabilized zirconia or partially stabilized zirconia to be employed in the piezoelectric/electrostrictive device 10 is stabilized or partially stabilized in the following manner. At least one compound, or two or more compounds selected from among yttrium oxide, ytterbium oxide, cerium oxide, calcium oxide, and magnesium oxide are added to zirconia to thereby stabilize or partially stabilize the zirconia.

Each of the compounds is added in the following amount: in the case of yttrium oxide or ytterbium oxide, 1 to 30 mol %, preferably 1.5 to 10 mol %; in the case of cerium oxide, 6 to 50 mol %, preferably 8 to 20 mol %; and in the case of calcium oxide or magnesium oxide, 5 to 40 mol %, preferably 5 to 20 mol %. Particularly, employment of yttrium oxide as a stabilizer is preferred. In this case, preferably, yttrium oxide is added in an amount of 1.5 to 10 mol % (more preferably, 2 to 4 mol % when mechanical strength is regarded as particularly important, or 5 to 7 mol % when endurance reliability is regarded as particularly important).

Alumina, silica, a transition metal oxide, or the like can be added to zirconia as a sintering aid or the like in an amount of 0.05 to 20 wt %. In the case where the piezoelectric/electrostrictive elements 14 are formed through film formation and monolithic firing, addition of alumina, magnesia, a transition metal oxide, or the like is preferred.

In the case where at least one of the stationary portion 11, the thin-plate portion 12, and the holding portion 13 is formed from a ceramic material, in order to obtain a ceramic material having a high mechanical strength and stable crystal phase, the average crystal grain size of zirconia is preferably regulated to 0.05 to 3 μm, more preferably 0.05 to 1 μm. As described above, the thin-plate portions 12 may be formed from a ceramic material similar to (but different from) that employed to form the holding portions 13 and the stationary portion 11. However, preferably, the thin-plate portions 12 are formed from a material substantially identical to that of the holding portions 13 and the stationary portion 11 in view of enhancement of the reliability of joint portions, enhancement of the strength of the piezoelectric/electrostrictive device 10, and simplification of a procedure for manufacturing the piezoelectric/electrostrictive device 10.

A piezoelectric/electrostrictive device can employ a piezoelectric/electrostrictive element of a unimorph type, a bimorph type, or the like. However, the unimorph type, in which the thin-plate portions 12 and corresponding piezoelectric/electrostrictive elements are combined together, is advantageous in terms of stability of displacement quantity, a reduction in weight, and easy design for avoiding occurrence of opposite orientations between stress generated in the piezoelectric/electrostrictive element and strain associated with deformation of the piezoelectric/electrostrictive device. Therefore, the unimorph type is suitable for the piezoelectric/electrostrictive device 10.

When, as shown in FIG. 1, the piezoelectric/electrostrictive elements 14 are formed in such a manner that one end of each of the piezoelectric/electrostrictive elements 14 is located on the stationary portion 11 (or the corresponding holding portion 13), whereas the other end is located on the lateral surface of the corresponding thin-plate portion 12, the thin-plate portions 12 can be driven to a greater extent.

Preferably, the piezoelectric/electrostrictive layers 14b1 to 14b4 are formed from a piezoelectric ceramic material. Alternatively, the piezoelectric/electrostrictive layers 14b1 to 14b4 may be formed from an electrostrictive ceramic material, a ferroelectric ceramic material, or an antiferroelectric ceramic material. In the case where, in the piezoelectric/electrostrictive device 10, the linearity between the displacement quantity of the holding portions 13 and a drive voltage (or output voltage) is regarded as important, preferably, the piezoelectric/electrostrictive layers 14b1 to 14b4 are formed from a material having low strain hysteresis. Therefore, preferably, the piezoelectric/electrostrictive layers 14b1 to 14b4 are formed from a material having a coercive electric field of 10 kV/mm or less.

A specific material for the piezoelectric/electrostrictive layers 14b1 to 14b4 is a ceramic material containing, singly or in combination, lead zirconate, lead titanate, magnesium lead niobate, nickel lead niobate, zinc lead niobate, manganese lead niobate, antimony lead stannate, manganese lead tungstate, cobalt lead niobate, barium titanate, sodium bismuth titanate, potassium sodium niobate, strontium bismuth tantalate, and the like.

Particularly, a material containing, as a primary component, lead zirconate, lead titanate, or magnesium lead niobate, or a material containing, as a primary component, sodium bismuth titanate is preferred as a material for the piezoelectric/electrostrictive layers 14b1 to 14b4, from the viewpoints of high electromechanical coupling coefficient, high piezoelectric constant, low reactivity with the thin-plate (ceramic) portion 12 during sintering of the piezoelectric/electrostrictive layers 14b1 to 14b4, and attainment of consistent composition.

Furthermore, there can be employed, as a material for the piezoelectric/electrostrictive layers 14b1 to 14b4, a ceramic material containing an oxide of, for example, lanthanum, calcium, strontium, molybdenum, tungsten, barium, niobium, zinc, nickel, manganese, cerium, cadmium, chromium, cobalt, antimony, iron, yttrium, tantalum, lithium, bismuth, or tin. In this case, incorporation of lanthanum or strontium into lead zirconate, lead titanate, or magnesium lead niobate, which is a primary component, may yield in some cases such an advantage that coercive electric field and a piezoelectric characteristic become adjustable.

Notably, addition of a material prone to vitrify, such as silica, to a material for the piezoelectric/electrostrictive layers 14b1 to 14b4 is desirably avoided. This is because, silica or a similar material is prone to react with a piezoelectric/electrostrictive material during thermal treatment of the piezoelectric/electrostrictive layers 14b1 to 14b4; as a result, the composition of the piezoelectric/electrostrictive material varies with a resultant deterioration in the piezoelectric property.

Meanwhile, preferably, the electrodes 14a1 to 14a5 of the piezoelectric/electrostrictive elements 14 are formed from a metal that is solid at room temperature and has excellent electrical conductivity. Examples of the metal include aluminum, titanium, chromium, iron, cobalt, nickel, copper, zinc, niobium, molybdenum, ruthenium, palladium, rhodium, silver, tin, tantalum, tungsten, iridium, platinum, gold, lead, and an alloy of these metals. Furthermore, an electrode material can be a cermet material prepared by dispersing in any of the above metals a material identical to that of the piezoelectric/electrostrictive layers 14b1 to 14b4 or that of the thin-plate portions 12.

Selection of an electrode material for use in the piezoelectric/electrostrictive element 14 depends on a method of forming the piezoelectric/electrostrictive layers 14b1 to 14b4. For example, in the case where the electrode 14a1 is formed on the thin-plate portion 12, and then the piezoelectric/electrostrictive layer 14b1 is formed on the electrode 14a1 through firing, the electrode 14a1 must be formed of a high-melting-point metal, such as platinum, palladium, a platinum-palladium alloy, or a silver-palladium alloy, which remains intact even when exposed to a firing temperature of the piezoelectric/electrostrictive layer 14b1. This also applies to other electrodes (electrodes 14a2 to 14a4) whose formation is followed by firing of corresponding piezoelectric/electrostrictive layers.

In contrast, in the case of the outermost electrode 14a5 to be formed on the piezoelectric/electrostrictive layer 14b4, the formation of the electrode 14a5 is not followed by firing of a piezoelectric/electrostrictive layer. Thus, the electrode 14a5 can be formed from a material containing, as a primary component, a low-melting-point metal, such as aluminum, gold, or silver.

Since the laminar electrodes 14a1 to 14a5 possibly cause a reduction in displacement of the piezoelectric/electrostrictive element 14, each of the electrode layers is desirably thin. Particularly, the electrode 14a5, which is formed after the piezoelectric/electrostrictive layer 14b4 is fired, is formed preferably from an organic metal paste, which enables the formation of a dense, very thin film after firing. Examples of the paste include a gold resinate paste, a platinum resinate paste, and a silver resinate paste.

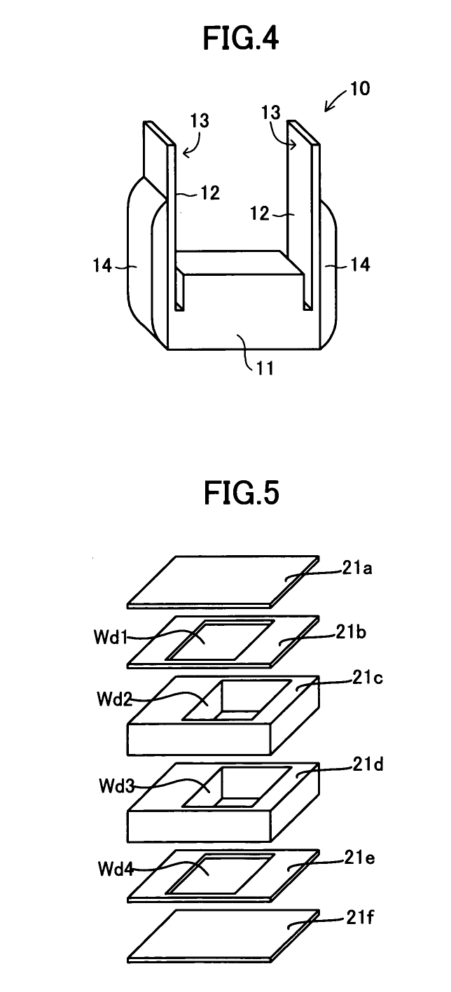

In the piezoelectric/electrostrictive device 10 of FIG. 1, the holding portions 13, which are formed integrally with the corresponding tip end portions of the thin-plate portions 12, have a thickness greater than the thickness Dd of the thin-plate portions 12. However, as shown in FIG. 4, the holding portions 13 may have a thickness almost equal to that of the thin-plate portions 12. As a result, an object to be held between the holding portions 13 can have a size corresponding to the distance between the thin-plate portions 12. In this case, regions where an adhesive is applied in order to hold the object substantially serve as the corresponding holding portions 13. Furthermore, in this case, a projection for specifying the region where an adhesive is applied may be provided. Desirably, such a projection is formed from the same material as that of the thin-plate portion 12, and integrated with the thin-plate portion 12 through monolithic sintering or monolithic molding.

The aforementioned piezoelectric/electrostrictive device 10 can also be employed as an ultrasonic sensor, an acceleration sensor, an angular-velocity sensor, an impact sensor, a mass sensor, or a similar sensor. In application to such a sensor, the piezoelectric/electrostrictive device 10 is advantageous in that sensor sensitivity can be readily adjusted by appropriately regulating the size of an object to be held between the opposed holding portions 13 or between the opposed thin-plate portions 12.

Next will be described a method for manufacturing the aforementioned piezoelectric/electrostrictive device 10. Preferably, a substrate portion (which excludes the piezoelectric/electrostrictive elements 14; i.e., which includes the stationary portion 11, the thin-plate portions 12, and the holding portions 13) of the piezoelectric/electrostrictive device 10 is manufactured by a ceramic green sheet lamination process. Meanwhile, preferably, the piezoelectric/electrostrictive elements 14 are manufactured by a film formation process, which is adapted to form a thin film, a thick film, or a similar film.

A ceramic green sheet lamination process allows integral formation of members of the substrate portion of the piezoelectric/electrostrictive device 10. Thus, employment of a ceramic green sheet lamination process allows a joint portion between members to be almost free from a change in state with passage of time, thereby enhancing the reliability of joint portions and securing rigidity. In the case where the substrate portion is formed by laminating metallic plates, employment of a diffusion joining process allows a joint portion between members to be almost free from a change in state with passage of time, thereby securing the reliability of joint portions, and rigidity.

In the piezoelectric/electrostrictive device 10 of FIG. 1 according to the present embodiment, boundary portions point portions) between the thin-plate portions 12 and the stationary portion 11, and boundary portions (joint portions) between the thin-plate portions 12 and the corresponding holding portions 13 serve as fulcrum points for manifestation of displacement. Therefore, the reliability of the joint portions is an important factor that determines the characteristics of the piezoelectric/electrostrictive device 10.

A manufacturing method to be described below features high productivity and excellent formability and thus can yield the piezoelectric/electrostrictive devices 10 having a predetermined shape within a short period of time with good reproducibility.

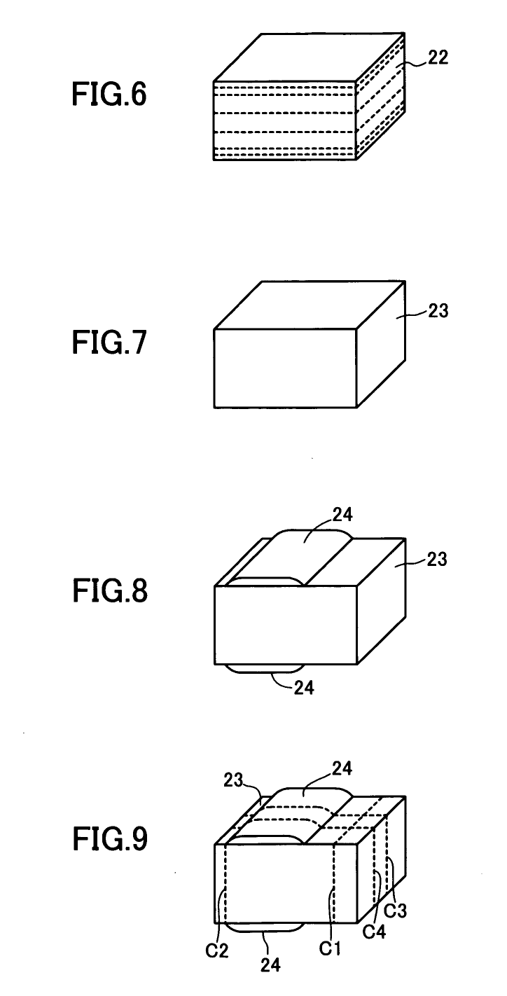

In the following description, a laminate obtained by laminating a plurality of ceramic green sheets is defined as a ceramic green sheet laminate 22 (see FIG. 6); and a monolithic body obtained by firing the ceramic green sheet laminate 22 is defined as a ceramic laminate 23 (see FIG. 7).

The manufacturing method is embodied desirably as follows: a single sheet equivalent to a plurality of ceramic laminates of FIG. 7 arranged lengthwise and crosswise is prepared; a laminate corresponding to a plurality of laminates 24 (see FIG. 8), which are formed into the piezoelectric/electrostrictive elements 14, is formed continuously on the surfaces of the sheet in predetermined regions; and the sheet is cut, whereby a plurality of piezoelectric/electrostrictive devices 10 are manufactured in the same process. Furthermore, desirably, two or more piezoelectric/electrostrictive devices 10 are yielded in association with a single window (including Wd1 and the like shown in FIG. 5). In order to simplify description, the following description discusses a method for obtaining a single piezoelectric/electrostrictive device 10 from a ceramic laminate by cutting the ceramic laminate.

Firstly, a binder, a solvent, a dispersant, a plasticizer, and the like are mixed with ceramic powder of zirconia or the like, thereby preparing a slurry. The slurry is defoamed. By use of the defoamed slurry, a rectangular ceramic green sheet having a predetermined thickness is formed by a reverse roll coater process, a doctor blade process, or a similar process.

Subsequently, as shown in FIG. 5, if necessary, a plurality of ceramic green sheets 21ato 21fare formed from the above-prepared ceramic green sheet by blanking with a die, laser machining, or similar machining.

In the example of FIG. 5, rectangular windows Wd1 to Wd4 are formed in the ceramic green sheets 21b to 21e, respectively. The windows Wd1 and Wd4 have almost the same shape, and the windows Wd2 and Wd3 have almost the same shape. Each of the ceramic green sheets 21a and 21f includes a portion that is formed into the thin-plate portion 12. Each of the ceramic green sheets 21b and 21e includes a portion that is formed into the holding portion 13. Notably, the number of ceramic green sheets is given merely as an example. In the illustrated example, the ceramic green sheets 21c and 21d may be replaced with a single green sheet having a predetermined thickness or with a plurality of ceramic green sheets to be laminated so as to attain the predetermined thickness or with a green sheet laminate having the predetermined thickness.

Thereafter, as shown in FIG. 6, the ceramic green sheets 21a to 21f are laminated and compression-bonded to thereby form the ceramic green sheet laminate 22. Subsequently, the ceramic green sheet laminate is fired to thereby form the ceramic laminate 23 shown in FIG. 7.

No particular limitation is imposed on the number and order of compression-bonding operations for forming the ceramic green sheet laminate 22 (for monolithic lamination). In the case where there exists a portion to which pressure is not sufficiently transmitted by uniaxial application of pressure (application of pressure in a single direction), desirably, compression bonding is repeated a plurality of times, or impregnation with a pressure-transmitting substance is employed in compression bonding. Also, for example, the shape of the windows Wd1 to Wd4 and the number and thickness of ceramic green sheets can be appropriately determined in accordance with the structure and function of the piezoelectric/electrostrictive device 10 to be manufactured.

When the above compression bonding for monolithic lamination is performed under application of heat, a more reliable state of lamination is obtained. When a paste, a slurry, or the like that contains a predominant amount of a ceramic powder and a binder and serves as a bonding aid layer is applied to ceramic green sheets by means of coating or printing before the ceramic green sheets are compression-bonded, the state of bonding at the interface between the ceramic green sheets can be enhanced. In this case, preferably, the ceramic powder to be employed as a bonding aid has a composition identical to or similar to a ceramic material employed in the ceramic green sheets 21a to 21f in view of the reliability of bonding. Furthermore, in the case where the ceramic green sheets 21a and 21f are thin, the use of a plastic film (particularly, a polyethylene terephthalate film coated with a silicone-based parting agent) is preferred in handling the ceramic green sheets 21a and 21f. When the windows Wd1 and Wd4 and the like are to be formed in relatively thin sheets, such as the ceramic green sheets 21b and 21e, each of these sheets may be attached to the aforementioned plastic film before a process for forming the windows Wd1 and Wd4 and the like is performed.

Subsequently, as shown in FIG. 8, the piezoelectric/electrostrictive laminates 24 are formed on the corresponding opposite sides of the ceramic laminate 23; i.e., on the corresponding surfaces of the fired ceramic green sheets 21a and 21f. Examples of methods for forming the piezoelectric/electrostrictive laminates 24 include thick-film formation processes, such as a screen printing process, a dipping process, a coating process, and an electrophoresis process; and thin-film formation processes, such as an ion beam process, a sputtering process, a vacuum deposition process, an ion plating process, a chemical vapor deposition (CVD) process, and a plating process.

Employment of such a film formation process in formation of the piezoelectric/electrostrictive laminates 24 allows the piezoelectric/electrostrictive laminates 24 and the thin-plate portions 12 to be monolithically bonded (disposed) without use of adhesive, thereby securing reliability and reproducibility and facilitating integration.

In this case, more preferably, a thick-film formation process is employed for forming the piezoelectric/electrostrictive laminates 24. A thick-film formation process allows, in film formation, the use of a paste, a slurry, a suspension, an emulsion, a sol, or the like containing, as a primary component, piezoelectric ceramic particles or powder having an average particle size of 0.01 to 5 μm, preferably 0.05 to 3 μm. The piezoelectric/electrostrictive laminates 24 obtained by firing the thus-formed films exhibit a good piezoelectric/electrostrictive characteristic.

An electrophoresis process has such an advantage that a film can be formed with high density and high shape accuracy. A screen printing process can simultaneously perform control of film thickness and pattern formation and thus can simplify a manufacturing process.

An example method for forming the ceramic laminate 23 and the piezoelectric/electrostrictive laminates 24 will be described in detail. Firstly, the ceramic green sheet laminate 22 is monolithically fired at a temperature of 1,200 to 1,600° C., thereby yielding the ceramic laminate 23 shown in FIG. 7. Thereafter, as shown in FIG. 3, the electrodes 14a1 are printed on the corresponding opposite sides of the ceramic laminate 23 at a predetermined position, followed by firing. Subsequently, the piezoelectric/electrostrictive layers 14b1 are printed and fired. The electrodes 14a2 are printed on the corresponding piezoelectric/electrostrictive layers 14b1, followed by firing. Such an operation is repeated a predetermined number of times to thereby form the piezoelectric/electrostrictive laminates 24. Thereafter, a terminal (not illustrated) for electrically connecting the electrodes 14a1, 14a3, and 14a5 to a drive circuit, and a terminal (not illustrated) for electrically connecting the electrodes 14a2 and 14a4 to the drive circuit are printed and fired.

Alternatively, the piezoelectric/electrostrictive laminates 24 may be formed as follows. The bottom electrode 14a1 is printed and fired. Subsequently, the piezoelectric/electrostrictive layer 14b1 and the electrode 14a2 are printed and are then simultaneously fired. Thereafter, in a manner similar to that described above, a process in which a single piezoelectric/electrostrictive layer and a single electrode are printed and then simultaneously fired is repeated a predetermined number of times.

In this case, for example, the electrodes 14a1, 14a2, 14a3, and 14a4 are formed from a material containing, as a primary component, platinum (Pt); the piezoelectric/electrostrictive layers 14b1 to 14b 4 are formed from a material containing, as a primary component, lead zirconate titanate (PZT); the electrode 14a5 is formed from gold (Au); and the terminals are formed from silver (Ag). In this manner, materials are selected in such a manner that their firing temperature lowers in the ascending order of lamination. As a result, at a certain firing stage, a material(s) that has been fired is free from re-sintering, thereby avoiding occurrence of a problem, such as the exfoliation or cohesion of an electrode material.

The selection of appropriate materials allows the members of the piezoelectric/electrostrictive laminates 24 and the terminals to be sequentially printed and then monolithically fired in a single firing operation. Also, the piezoelectric/electrostrictive laminate 24 may be formed as follows: the firing temperature for the outermost piezoelectric/electrostrictive layer 14b4 is regulated to be higher than that for the piezoelectric/electrostrictive layers 14b1 to 14b3, so as to finally bring the piezoelectric/electrostrictive layers 14b1 to 14b4 into the same sintered state.

The members of the piezoelectric/electrostrictive laminates 24 and the terminals may be formed by a thin-film formation process, such as a sputtering process or a vapor deposition process. In this case, thermal treatment is not necessarily required.

The following simultaneous firing process may be employed. The piezoelectric/electrostrictive laminates 24 are formed on the corresponding opposite sides of the ceramic green sheet laminate 22; i.e., on the corresponding surfaces of the ceramic green sheets 21a and 21f. Subsequently, the ceramic green sheet laminate 22 and the piezoelectric/electrostrictive laminates 24 are simultaneously fired.

In an example method for simultaneously firing the piezoelectric/electrostrictive laminates 24 and the ceramic green sheet laminate 22, precursors of the piezoelectric/electrostrictive laminates 24 are formed by a tape formation process employing a slurry raw material, or a similar process; the precursors of the piezoelectric/electrostrictive laminates 24 are laminated on the corresponding opposite sides of the ceramic green sheet laminate 22 by thermo-compression bonding or a similar technique; and subsequently the precursors and the ceramic green sheet laminate 22 are simultaneously fired. However, in this method, the electrodes 14a1 must be formed in advance on the corresponding opposite sides of the ceramic green sheet laminate 22 and/or on the corresponding piezoelectric/electrostrictive laminates 24 by means of any film formation process described above.

In another method, the electrodes 14a1 to 14a5 and the piezoelectric/electrostrictive layers 14b1 to 14b4, which are component layers of the piezoelectric/electrostrictive laminates 24, are screen-printed at least on those portions of the ceramic green sheet laminate 22 which are finally formed into the corresponding thin-plate portions 12; and the component layers and the ceramic green sheet laminate 22 are simultaneously fired.

The firing temperature for a component layer of the piezoelectric/electrostrictive laminates 24 is appropriately determined on the basis of the material of the component layer, but is generally 500 to 1,500° C. The preferred firing temperature for the piezoelectric/electrostrictive layers 14b1 to 14b4 is 1,000 to 1,400° C. In this case, preferably, in order to control the composition of the piezoelectric/electrostrictive layers 14b1 to 14b4, sintering is performed in such a state that evaporation of the material of the piezoelectric/electrostrictive layers 14b1 to 14b4 is controlled (for example, in the presence of an evaporation source). In the case where the piezoelectric/electrostrictive layers 14b1 to 14b4 and the ceramic green sheet laminate 22 are simultaneously fired, their firing conditions must be compatible with each other. The piezoelectric/electrostrictive laminates 24 are not necessarily formed on the corresponding opposite sides of the ceramic laminate 23 or the ceramic green sheet laminate 22, but may be formed only on a single side of the ceramic laminate 23 or the ceramic green sheet laminate 22.

Subsequently, unnecessary portions are removed, through cutting, from the ceramic laminate 23 on which the piezoelectric/electrostrictive laminates 24 are formed as described above (hereinafter, a “monolithic body including the ceramic laminate 23 and the piezoelectric/electrostrictive laminate 24,” which partially constitutes the piezoelectric/electrostrictive device 10, may be referred to as an “object to be cut”). Specifically, the object to be cut is cut along cutting lines (broken lines) C1 to C4 shown in FIG. 9. Cutting can be performed through mechanical machining (e.g., wire sawing or dicing), laser machining (e.g., YAG laser machining or excimer laser machining), or electron beam machining. In the present embodiment, dicing is employed.

More specifically, firstly, the object to be cut is cut along the cutting lines C1 and C2. This cutting is performed such that the overall length of the piezoelectric/electrostrictive device 10 (i.e., the length between the end of the holding portions 13 and the end of the stationary portion 11) falls within a tolerance range of the finished length of the piezoelectric/electrostrictive device 10. That is, the overall length of the piezoelectric/electrostrictive device 10 is determined by means of cutting along the cutting lines C1 and C2.

Subsequently, the object to be cut is cut along the cutting lines C3 and C4. This cutting yields the piezoelectric/electrostrictive device 10 whose lateral end surfaces have not undergone the below-described polishing. This cutting is performed such that the thickness of the piezoelectric/electrostrictive device 10 (i.e., the length between two parallel lateral end surfaces of the piezoelectric/electrostrictive device 10 ) becomes greater by 50 μm than the finished thickness of the piezoelectric/electrostrictive device 10. The 50 μm-thick portion corresponds to a polishing allowance for the below-described polishing performed on the two cut surfaces formed through cutting along the cutting lines C3 and C4. That is, the thickness of the piezoelectric/electrostrictive device 10 is determined, not by cutting along the cutting lines C3 and C4, but by polishing subsequently performed on the two cut surfaces formed through the cutting.

The polishing allowance may be a size other than 50 μm. A large polishing allowance enables reduction of the surface roughness of the finished (polished) lateral end surface of the piezoelectric/electrostrictive device 10 (i.e., the finished lateral end surfaces of the piezoelectric/electrostrictive layers 14b1 to 14b4), but requires a long period of time for polishing. Therefore, the polishing allowance can be determined in consideration of the surface roughness of the finished lateral end surface, as well as the time required for polishing.

Desirably, dicing is performed in such a manner that the hole formed of the window Wd1 and other windows is filled with a filler (e.g., a wax or a resin), so as to prevent vibration of the thin-plate portions (portions corresponding to the ceramic green sheets 21a and 21f) during the course of dicing. After dicing, the filler may be removed through dissolution with an appropriate solvent, or may be burned out through heating/firing. Desirably, before dicing is performed, an organic resin, or a paste or the like containing an organic resin and a ceramic material is applied to the surfaces of the laminates 24, which are to be formed into the piezoelectric/electrostrictive elements 14, followed by drying and hardening, thereby forming a protective film (protective layer). The thickness of the protective film is preferably 1 to 500 μm, more preferably 20 to 100 μm. The protective film can be formed through printing, spraying, or a similar technique. The thickness of the outermost electrode layer of the piezoelectric/electrostrictive element can be increased so that the electrode layer serves as the protective film. Cutting along the cutting lines C3 and C4 is preferably performed through wire sawing.

Subsequently, polishing is performed on the two lateral end surfaces of the piezoelectric/electrostrictive device 10, which is obtained through cutting of the object to be cut as described above. Specifically, (non-polished) numerous piezoelectric/electrostrictive devices 10 are obtained through cutting along the cutting lines C1 to C4, and one of the two lateral end surfaces of each of the piezoelectric/electrostrictive devices 10 is attached onto the surface of a predetermined polishing jig (master plate) by use of a hot-melt wax, to thereby fixate each of the piezoelectric/electrostrictive devices 10 on the master plate.

Subsequently, the other of the two lateral end surfaces of each of the piezoelectric/electrostrictive devices 10 fixated on the mater plate (i.e., the lateral end surface which is exposed outward) is ground by use of a surface grinding machine employing a resin bond grinding wheel, to thereby decrease the thickness of the device by about 10 μm. Through this grinding, the thicknesses of the numerous piezoelectric/electrostrictive devices 10 are made equal to one another (i.e., the heights of the outwardly exposed lateral end surfaces from the master plate surface are made equal to one another).

Thereafter, each of the outwardly exposed lateral end surfaces is subjected to mirror-polishing by use of a lapping machine employing, as an abrasive material, a diamond slurry containing diamond particles having a particle size of 1 μm or less, to thereby decrease the thickness of the device by about 10 μm. Through this mirror-polishing, one of the two lateral end surfaces of each of the numerous piezoelectric/electrostrictive devices 10 (i.e., piezoelectric/electrostrictive layers 14b1 to 14b4) is finished.

Subsequently, the master plate is heated to melt the hot-melt wax, thereby removing the numerous piezoelectric/electrostrictive devices 10 from the master plate. Then, the numerous piezoelectric/electrostrictive devices 10 are inverted with respect to the master plate, and each of the above-finished lateral end surfaces is attached onto the surface of the master plate by use of a hot-melt wax, to thereby again fixate each of the piezoelectric/electrostrictive devices 10 on the master plate. Through this procedure, each of the non-finished lateral end surfaces is exposed outward.

Subsequently, in a manner similar to that described above, each of the non-finished lateral end surfaces is ground by use of a surface grinding machine employing the aforementioned resin bond grinding wheel, to thereby decrease the thickness of the device by about 10 μm. Thereafter, each of the thus-ground and non-finished lateral end surfaces is subjected to mirror-polishing by use of the aforementioned lapping machine employing, as an abrasive material, a diamond slurry containing diamond particles having a particle size of 1 μm or less, until the thickness of each of the piezoelectric/electrostrictive devices 10 falls within a tolerance range of the finished thickness of the piezoelectric/electrostrictive device 10. Through the above-described procedures, the two lateral end surfaces of each of the numerous piezoelectric/electrostrictive devices 10 (i.e., piezoelectric/electrostrictive layers 14b1 to 14b4) are finished. As described above, the two lateral end surfaces of each of the piezoelectric/electrostrictive devices 10 are polished. The decrease in thickness of the device through the above grinding or polishing may be appropriately varied.

Subsequently, the master plate is heated to melt the hot-melt wax, thereby removing the numerous piezoelectric/electrostrictive devices 10 from the master plate. Thereafter, in order to remove the hot-melt wax, ground chips, abrasive grains, or the like adhering onto the surfaces of the piezoelectric/electrostrictive devices 10, the devices 10 are placed in a predetermined cleaning tray, and washed with an ultrasonic cleaner by use of an aromatic hydrocarbon solvent, isopropyl alcohol (IPA), acetone, or a detergent such as an alkaline detergent.

Subsequently, the above-cleaned numerous piezoelectric/electrostrictive devices 10 are completely rinsed, and then vacuum-dried in a predetermined vacuum-dryer. Through the above-described procedures, the numerous piezoelectric/electrostrictive devices 10 (shown in FIG. 1) are manufactured simultaneously. Thereafter, the numerous piezoelectric/electrostrictive devices 10 may be further subjected to thermal treatment in air at 300° C. to 900° C. (more preferably 500° C. to 850° C.), to thereby burn out or remove various organic substances adhering onto the surfaces of the devices 10.

The surface roughness of the above-polished (finished) lateral end surfaces of each of the piezoelectric/electrostrictive devices 10 (i.e., piezoelectric/electrostrictive layers 14b1 to 14b4) can be appropriately regulated by controlling the polishing conditions (e.g., the type or particle size of an abrasive material to be employed). Specifically, for example, when diamond particles having a particle size of 3 μm or less were employed as an abrasive material, the maximum surface roughness (Ry) of the lateral end surfaces was regulated to 0.5 μm, whereas when diamond particles having a particle size of 0.5 μm or less were employed as an abrasive material, the maximum surface roughness (Ry) of the lateral end surfaces was regulated to 0.1 μm. The surface roughness is obtained as follows: the measurement surface (i.e., the lateral end surface of the piezoelectric/electrostrictive device 10) is subjected to gold sputtering (1,000 Å); and the surface roughness is measured by use of a laser microscope at predetermined points on the lateral end surfaces of the piezoelectric/electrostrictive layer in a direction parallel to the layer surfaces (i.e., in a direction parallel to the outer surface of the thin-plate portions 12) over a length of 0.05 mm. The surface roughness of the lateral end surfaces of the stationary portion 11 was also measured by use of a stylus-type surface roughness meter.

The above-described polishing, which is performed by use of a lapping machine employing a diamond slurry containing diamond particles serving as loose abrasive grains, may be performed by use of a predetermined abrasive paper. The thus-polished surface (i.e., the lateral end surface of the piezoelectric/electrostrictive device 10) may be further subjected to blast finishing, to thereby regulate the surface roughness of the polished surface. Alternatively, the polished surface may be subjected to any one of techniques including barrel polishing, reverse sputtering, ion milling, chemical etching, plasma etching, laser ablation, thermal etching, and thermal treatment, or subjected to an arbitrary combination of two or more of these techniques, to thereby regulate the surface roughness, surface strain, etc. of the polished surface.

Preferably, the aforementioned object to be cut (or the piezoelectric/electrostrictive device 10) is subjected to the above-described processes (from cutting to vacuum drying), while the object to be cut is bonded, at a predetermined position, with a thin-plate cut base (which is cut together with the object to be cut), such as a glass plate, a silicon wafer, or a plate or film formed of an organic resin material (e.g., PET, PC, PE, or PP) by use of an adhesive. In the case where such a cut base is bonded to the object to be cut, when, for example, the object is required to be moved during the above-described processes (including cutting and vacuum drying), the object can be moved by holding merely the cut base without direct contact with the object. Therefore, there can be prevented occurrence of defectives caused by, for example, unexpected bending, cracking, or staining of the object to be cut (or the piezoelectric/electrostrictive device 10).

Specifically, preferably, there is prepared, for example, one sheet having a structure equivalent to a structure in which a plurality of objects to be cut are arranged lengthwise and crosswise on a single plane; a thin-plate cut base is bonded, by use of an adhesive, onto the surface of the sheet before cutting of the sheet; and the cut base is cut together with the sheet, to thereby form (non-polished) piezoelectric/electrostrictive devices 10 onto which the cut base is bonded.

There was performed a test for determining the amount of dust generation, for the purpose of confirming that the amount of dust generation (due to particle separation) is reduced by forming the lateral end surfaces of the piezoelectric/electrostrictive devices 10 (i.e., the piezoelectric/electrostrictive layers 14b1 to 14b4) through cutting as described above, followed by polishing. The procedure and results of the test will next be described.

The dust generation amount determining test was performed through the following procedure.

1. A predetermined amount of ultrapure water is produced by use of a predetermined ultrapure water production apparatus.

2. A beaker is completely washed with the above-produced ultrapure water.

3. The above-produced ultrapure water (Q1 m³) is placed in the above-washed beaker.

4. The beaker containing the ultrapure water (Q1 m³) is applied to a US cleaner for one minute.

5. The number of particles contained in the ultrapure water (Q1 m³) in the beaker (i.e., the number of particles contained in the ultrapure water per se) is counted by use of a particle counter, and the number of particles (A) per unit volume of the ultrapure water is determined on the basis of the counting results.

6. After the number of the aforementioned particles is counted, a test sample is placed in the ultrapure water (Q2 m³) contained in the beaker, and the beaker is applied to the aforementioned US cleaner for one minute.

7. The number of particles contained in the ultrapure water (Q2 m³) in the beaker (i.e., the sum of the number of particles contained in the ultrapure water per se and the number of particles removed from the test sample) is counted by use of the aforementioned particle counter, and the number of particles (B) per unit volume of the ultrapure water is determined on the basis of the counting results.

8. The number of particles removed from the test sample; i.e., the amount of dust generation (N), is determined on the basis of the following formula: N=(B−A)·Q2.

The following three types of test samples (one for each type) were prepared:

No. 1: a test sample having non-polished lateral end surfaces (i.e., a piezoelectric/electrostrictive device 10 of FIG. 1 having non-polished lateral end surfaces);

No. 2: a test sample having non-polished lateral end surfaces which has undergone thermal treatment for separation of microcracks (i.e., a piezoelectric/electrostrictive device 10 of FIG. 1 having non-polished lateral end surfaces which has undergone thermal treatment at 300° C. to 800° C.); and No. 3: a test sample having polished lateral end surfaces (i.e., the product of the present invention, which corresponds to the aforementioned piezoelectric/electrostrictive device 10 of FIG. 1).

Table 1 shows the results of the dust generation amount determining test performed on the above three types of the test samples (i.e., three test samples).

TABLE 1

| | | Dust generation | |
|---|---|---|---|
| | | amount N | |
| No. | Test sample | (particles) | Note |
| 1 | Sample having non-polished | 10,000 to 30,000 | Comparative |
| | lateral end surfaces | | product |
| 2 | Sample of No. 1 which has | 5,000 to 10,000 | Comparative |
| | undergone thermal treatment | | product |
| 3 | Sample having polished | 5,000 to 10,000 | Invention |
| | lateral end surfaces | | product |

As is clear from Table 1, when a sample having non-polished lateral end surfaces is subjected to the aforementioned thermal treatment for separation of microcracks, or to polishing of the lateral end surfaces, the amount of dust generation (N) caused by particle separation is reduced.

As described above, the piezoelectric/electrostrictive device of the present invention can be employed as active elements, such as various transducers, various actuators, frequency-domain functional components (filters), transformers, vibrators and resonators for use in communication and power applications, oscillators, and discriminators; and also as sensor elements for use in various sensors, such as ultrasonic sensors, acceleration sensors, angular-velocity sensors, impact sensors, and mass sensors. In addition, the piezoelectric/electrostrictive device can be employed as various actuators for use in mechanisms for displacement, positioning adjustment, or angle adjustment of various precision components in optical equipment, precision equipment, and similar equipment.

The piezoelectric/electrostrictive layer of the piezoelectric/electrostrictive device has a lateral end surface (cut surface or worked surface) (serving as a lateral end surface of the piezoelectric/electrostrictive element (piezoelectric/electrostrictive device), which forms the single flat surface, and has an arithmetic average surface roughness of 0.05 μm or less. The lateral end surface can be formed by preparing a rough surface through cutting by means of dicing, followed by finishing of the rough surface through polishing.

This finishing of the rough surface through polishing reduces the surface roughness of the lateral end surface of the piezoelectric/electrostrictive layer to 0.05 μm or less, whereby uniform residual strain (i.e., residual stress) occurs in the vicinity of the lateral end surface. Therefore, when, for example, the piezoelectric/electrostrictive layer is deformed during operation of the piezoelectric/electrostrictive device, local occurrence of abnormally high stress (stress concentration) in the vicinity of the lateral end surface is prevented, and thus particle separation tends not to occur.

Microcracks generated in the vicinity of the lateral end surface (i.e., the aforementioned rough surface) of the piezoelectric/electrostrictive layer through application of load during the course of dicing can be eliminated by means of polishing performed on the rough surface. Thus, even when repeated stress generated through operation of the piezoelectric/electrostrictive device is applied to the piezoelectric/electrostrictive layer (i.e., even when the piezoelectric/electrostrictive layer is deformed repeatedly), particle separation, which is caused by growth of the microcracks, does not occur.

Therefore, the piezoelectric/electrostrictive device which has undergone dicing is not required to be subjected to the aforementioned thermal treatment for elimination of microcracks in order to prevent particle separation from the lateral end surface of the piezoelectric/electrostrictive layer, the thermal treatment causing productivity reduction. In addition, the dicing speed can be increased; i.e., the time required for the dicing can be shortened, since polishing, etc. is performed after the dicing, and thus the surface roughness of the rough surface formed by the dicing is not necessarily regulated to a relatively small level.

Thus, according to the present invention, there is provided, at high productivity, a piezoelectric/electrostrictive device which can be employed in the environment in which particle separation from the lateral end surface thereof should be suppressed to the lowest possible level; i.e., a piezoelectric/electrostrictive device which can be employed as, for example, an actuator for controlling the position of a magnetic head of a hard disk drive.

The present invention is not limited to the above-described embodiment, and various modifications may be made without departing from the scope of the invention. For example, in the above-described embodiment, after the object to be cut is cut along the cutting lines C1 and C2 shown in FIG. 9, the object is cut along the cutting lines C3 and C4 of FIG. 9. However, the object to be cut may be cut along the cutting lines C3 and C4 before cutting of the object along the cutting lines C1 and C2.

In the above-described embodiment, after completion of cutting of the object to be cut (i.e., the piezoelectric/electrostrictive device), the lateral end surfaces of the piezoelectric/electrostrictive device are ground by use of a surface grinding machine, and then finished through polishing by use of a lapping machine. However, after completion of cutting of the object to be cut (i.e., the piezoelectric/electrostrictive device), the step of grinding the lateral end surfaces of the piezoelectric/electrostrictive device by use of a surface grinding machine may be omitted, and the lateral end surfaces of the piezoelectric/electrostrictive device may be finished merely through polishing by use of a lapping machine.

In the above-described embodiment, the piezoelectric/electrostrictive element 14 includes a plurality of electrodes 14a1 to 14a5 and a plurality of piezoelectric/electrostrictive layers 14b1 to 14b4. However, the piezoelectric/electrostrictive element may be formed of a pair of electrodes, and a single piezoelectric/electrostrictive layer sandwiched between the paired electrodes.

In the case where the stationary portion 11, the thin-plate portions 12, and the holding portions 13 are formed from a metal, in place of the ceramic laminate 23 shown in FIG. 7, a metal structure having the same shape as that of the ceramic laminate may be formed through casting. Alternatively, metal thin plates whose shapes are identical to those of the ceramic green sheets shown in FIG. 5 may be prepared, and laminated together by a cladding process to thereby form a metal structure having the same shape as that of the ceramic laminate 23.

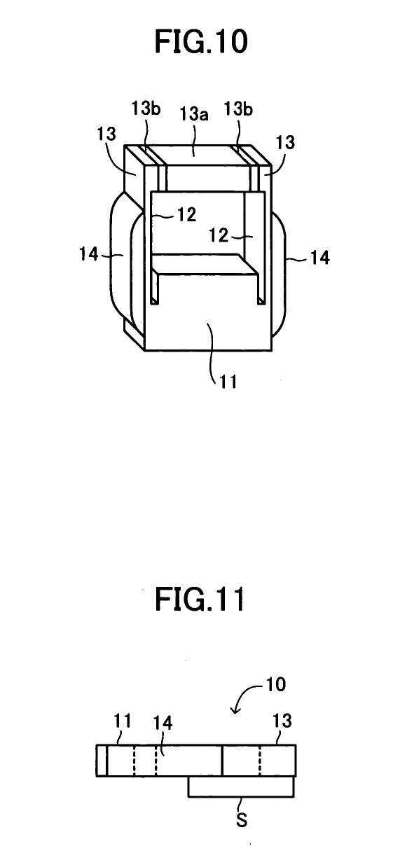

In the piezoelectric/electrostrictive device 10 of the above-described embodiment, an object is held between the paired holding portions 13. However, as shown in FIG. 10, a spacer 13 a may be held between the paired holding portions 13 via adhesives 13b. Furthermore, as shown in FIG. 11, an object may be held on lateral end surfaces (on lower surfaces in FIG. 11) of the holding portions of the piezoelectric/electrostrictive device according to the above-described embodiment by means of bonding or a similar technique.

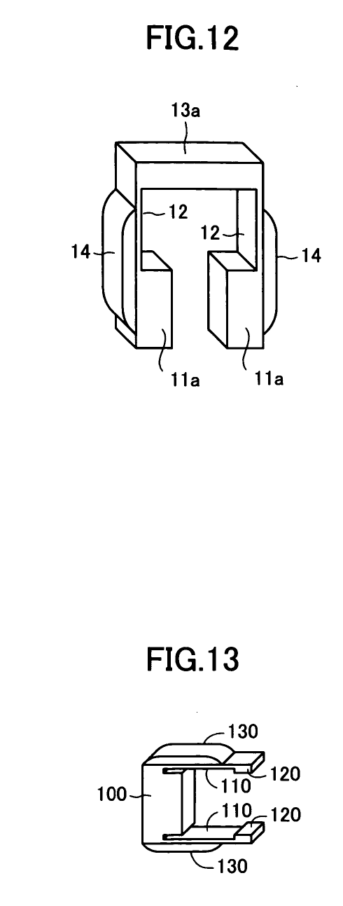

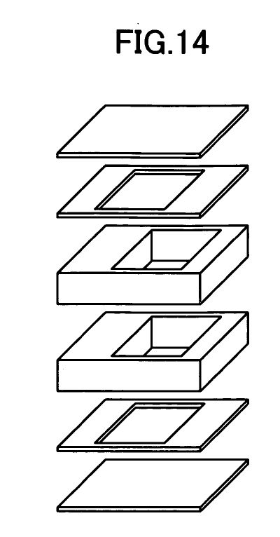

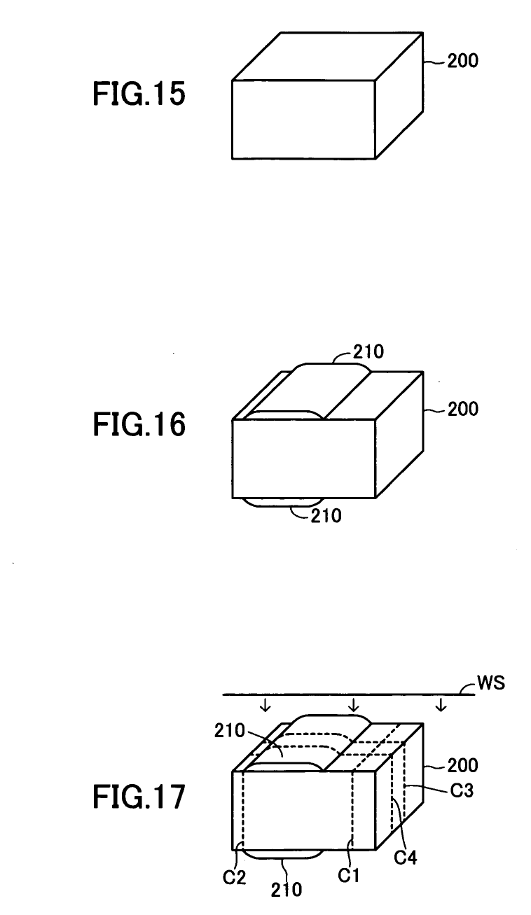

Furthermore, the structure shown in FIG. 12 may be employed. Specifically, a central portion of the stationary portion 11 in the above-described embodiment is cut off to thereby form a pair of stationary portions 11a , so that the stationary portions 11a support the corresponding thin-plate portions 12. Tip end portions of the paired thin-plate portions 12 may be integrally connected to thereby form a holding portion 13a.

In the piezoelectric/electrostrictive device 10 of the above-described embodiment, the thickness of the tip end portions of the thin-plate portions 12 (i.e., the holding portions 13) is regulated to be greater than that of the thickness (Dd) of the thin-plate portions 12 (see FIG. 1). However, as shown in FIG. 4, the thickness of the tip end portions of the thin-plate portions 12 may be regulated to be equal to that of the thickness (Dd), and each of the tip end portions may be outwardly bent at a predetermined angle. With this configuration, an object to be held between the paired thin-plate portions 12 is readily inserted through the tip end portions. In addition, when an object to be held is fixated through bonding, an adhesive is readily applied to the bonding surfaces.

Alternatively, the thickness of the tip end portions of the thin-plate portions 12 may be regulated to be equal to that of the thickness (Dd), and each of the tip end portions may be inwardly bent at a predetermined angle. With this configuration, when an object to be held is fixated through bonding, exfoliation of the object tends not to occur due to increased bonding strength.

When the lateral end surfaces of the piezoelectric/electrostrictive device 10 of the above-described embodiment are polished, cracks may be generated in the thin-plate portions 12, or at the boundary between the thin-plate portions 12 and the stationary portion 11. In such a case, the lateral end surfaces (i.e., the polished surfaces) assume mirror surfaces, and therefore, the cracks are difficult to detect by use of a reflection metallurgical microscope or stereoscopic microscope.

However, when incident light is caused to enter the substrate portion by use of a field stop, the cracks can be detected. This crack detection is based on the mechanism by which the incident light is scattered within the substrate portion, and the thus-scattered light is blocked at the boundaries of cracks, whereby crack generation sites become conspicuous. Similar to the case described above, cracks can be detected through observation by use of transmitted light. However, this detection requires a transparent jig for holding the piezoelectric/electrostrictive device 10.

Cracks generated in the thin-plate portions 12 (vibration plates) can be detected through a method utilizing the resonance frequency of the vibration plates. Specifically, this method, which is based on the phenomenon that the resonance frequency of the vibration plates decreases due to crack generation, detects cracks when the resonance frequency of the vibration plates becomes lower than a predetermined normal range.

However, the smaller the size of cracks, the smaller the amount of a decrease in the resonance frequency due to generation of the cracks. Therefore, when small cracks are generated in a vibration plate, the resonance frequency of the vibration plate may fall within a predetermined normal range, leading to failure of detection of the small cracks. In order to avoid such detection failure, before measurement of the resonance frequency of the vibration plate, the vibration plate must be subjected to a treatment for sufficient growth of the cracks generated in the plate, such that the resonance frequency of the vibration plate becomes lower than the aforementioned predetermined normal range.

Examples of the treatment for growth of the cracks generated in a vibration plate include a treatment in which the frequency of a drive signal for driving the piezoelectric/electrostrictive device 10 is swept within a predetermined frequency range (including the resonance frequency of the vibration plate) at a predetermined cycle for a predetermined period of time. In this treatment, the voltage of the drive signal (i.e., drive power) is appropriately determined to a level such that the cracks which have already been generated in a vibration plate can be grown, and that a crack-free vibration plate is not broken (i.e., new cracks are not generated in the crack-free vibration plate), as well as the resonance frequency of the vibration plate is determined in accordance with the breakdown strength of the vibration plate.

1. A piezoelectric/electrostrictive device comprising:
a thin-plate portion;
a stationary portion supporting the thin-plate portion; and
a piezoelectric/electrostrictive element formed at least on a flat surface of the thin-plate portion, the piezoelectric/electrostrictive element including a plurality of electrodes and at least one piezoelectric/electrostrictive layer which are laminated together, a lateral end surface of the piezoelectric/electrostrictive element, which forms a single flat surface, being composed of respective lateral end surfaces of the plurality of electrodes and a lateral end surface of said at least one piezoelectric/electrostrictive layer, characterized in that the lateral end surface of the piezoelectric/electrostrictive layer has an arithmetic average surface roughness of 0.05 μm or less.

2. A piezoelectric/electrostrictive device according to claim 1, wherein the lateral end surface of the piezoelectric/electrostrictive layer is formed by polishing the lateral end surface of the piezoelectric/electrostrictive element, which forms the single flat surface.
